(19) United States
(12) Patent Application Publication
(10) Pub. No.: US 2008/0042171 A1
(43) Pub. Date: Feb. 21, 2008

(54) Transistor arrangement, sense-amplifier arrangement and methods of manufacturing the same via a phase shift mask

(76) Inventors: Sebastian Mosler, Dresden (DE); Mario Hennig, Dresden (DE); Karsten Zeiler, Munchen (DE); Thi Phuong Hoa Nguyen, Forchheim (DE); Rainer Pforr, Dresden (DE); Jorg Thiele, Vaterstetten (DE)

Correspondence Address: EDELL, SHAPIRO & FINNAN, LLC, 1901 RESEARCH BLVD., SUITE 400, ROCKVILLE, MD, 20850, US

(21) Appl. No.: 11/506,205

(22) Filed: Aug. 18, 2006

(51) Int. Cl. H01L 29/76; H01L 21/8234; H01L 27/108; H01L 21/8242

(52) U.S. Cl. 257/288; 438/197; 438/239; 257/296

(57) ABSTRACT

Methods of forming transistor arrangements using alternating phase shift masks are provided. The mask may include two parallel opaque lines, a first transparent section separating the opaque lines and a second transparent section in the rest. The second transparent section may shift the phase with respect to the first transparent section by 180 degree. A phase conflict occurs along an edge between the first and the second transparent sections. A semiconductor substrate is patterned via the mask and, from the opaque lines functional active areas of a transistor pair and from the phase conflict edge, thereby resulting in a parasitic area. A separation gate is provided that is capable of switching off a parasitic transistor being formed within the parasitic area. Channel widths may be stabilized and maximized within dense transistor arrangements, for example, in a multiplexer portion of a sense amplifier arrangement for memory cell arrays.

### FIELD OF THE INVENTION

The invention relates to a transistor arrangement comprising a transistor pair. The invention relates further to a sense amplifier arrangement comprising a plurality of transistor pairs and to methods of manufacturing a transistor arrangement and a sense-amplifier arrangement via alternating phase shift masks.

### BACKGROUND

Resolution enhancement techniques (RETs) push optical lithography to extend to sub-wavelength regions for very low KI patterning processes. Effective RETs require for example dissection of the respective layout in two separate photolithographic masks, wherein a first mask is related to dense, repetitive structures and wherein a second mask relates to non-repetitive “isolated” structures. The wafer is exposed sequentially to the first and the second mask, wherein the dissected layout is transferred into a semiconductor wafer. In a production environment, double exposure halves the exposure capacities and doubles the mask production costs.

Alternating phase shift masks (altPSMs) are a single exposure RET which can effectively enhance the resolution of a conventional optical lithography system. AltPSMs introduce a 180-degree phase shift in the light transmitted on opposing sides of a critical feature on a photo mask. By utilizing the destructive interference of phase-shifted light, altPSMs facilitate the transfer of narrow “isolated” and “semi-isolated” structures, wherein a comparatively wide process window for the exposure process is achievable. The use of alternating phase shift masks in single exposure processes is conventionally limited to closed line structures that facilitate a separation of two transparent sections of the mask that shift the phase differently. Topologies comprising T-junctions and open lines, however, create phase conflicts, since an edge between two transparent sections of different phase in the photo mask creates a parasitic line in the patterned substrate.

Layouts of dense memory cell arrays and dense sense-amplifier circuits, e.g., the layout of the active areas of the selection transistors, the layout of the word lines addressing the selection transistors, and the layout of a first metal layer comprising data lines are typically open line topologies. Thus, phase shift masks are typically not applicable in connection with the formation of dense memory cell arrays.

A specific exception thereof is a dynamic random access memory (DRAM) cell array that bases on a memory cell comprising a selection transistor and a trench capacitor. The selection transistor includes two source/drain regions and a channel region that are formed within a line-shaped active area within a semiconductor substrate. The trench capacitor is formed along a trench being etched into the semiconductor substrate, wherein the trenches intersect separate neighboring active areas arranged along a cell line. A phase conflict between two transparent mask sections of different phase may then be limited to the region of the trench opening, wherein the formation of the trench eliminates parasitic structures resulting from the phase conflict. Using such techniques for solving phase conflicts in open line topologies is typically restricted to layouts that provide additional features that substitute parasitic structures in course of the formation of the additional features.

In the following the layout requirements of a sense amplifier arrangement are described. Data is written into a DRAM memory cell by applying a potential representing the data to a bit line that is connected to a first source/drain region of a selection transistor. By switching the selection transistor into the conductive state, a storage capacitor connected to a second source/drain region of the selection transistor is charged or discharged. A plurality of memory cells share the same bit line. When a memory cell is read out, the selection transistor is switched into the conductive state and the charge state of the storage capacitor is checked via a sense amplifier arrangement. The sense amplifier arrangement conditions the data signal from the selected storage capacitor, routes the data signal to a comparator unit and compares the data signal to a reference signal.

The sense amplifier arrangement comprises a plurality of isolation transistors for temporarily switching the respective bit line to the sense amplifier arrangement, a plurality of equalizer transistors biasing in each case a pair of neighboring bit lines and a plurality of precharge transistors connecting a plurality of selected bit lines to a precharge circuit. The pitch of the bit lines is determined by the cell array layout, which is designed to be as dense as possible. The number of isolation transistors corresponds to the number of bit lines, wherein the isolation transistors are split up in two columns confining the cell array on opposing sides. Thus, the pitch of the isolation transistors is twice the pitch of the bit lines.

The channel width of an isolation transistor with an active area elongating in a longitudinal direction along the bit lines is determined by the width of the active area. To ensure uniform isolation transistor properties, a stable line width of the active areas is required, wherein the line width may remain as unaffected as possible by process fluctuations. With the pitch of the isolation transistors that is predetermined by the dense memory cell array, a line width that is as large as possible is required for the isolation transistors.

### SUMMARY

The invention relates to a method of forming a transistor pair via an alternating phase shift mask. The method includes providing a photo mask that comprises opaque features including a pair of parallel opaque lines being separated by a gap. The photo mask comprises further a first transparent section filling the gap between the opaque lines and a second transparent section extending outside the gap from one of the opaque line to the other and facing the first transparent section at the opaque lines at least in sections. A phase shift of the second transparent section differs from that of the first transparent section. The method comprises further patterning a semiconductor substrate by exposing the photo mask, wherein from the opaque lines functional active areas of the transistor pair result in the semiconductor substrate. The functional active areas extend essentially along a longitudinal direction between a first and a second end respectively and are arranged in a column direction that intersects the longitudinal direction. Due to a phase conflict between the transparent sections, at least one parasitic active area is formed that connects the functional active areas at the respective first ends. A separation gate is provided above the parasitic active area. A supply unit is provided, that is capable of switching off a parasitic transistor comprising a parasitic channel region being formed within the parasitic active area below the separation gate. The method facilitates dense columnar arrangements of wide transistors using alternating phase shift masks.

The invention relates to a method of forming an equalizing/precharge portion of a sense amplifier arrangement, wherein a photo mask is provided that comprises opaque features including a plurality of pairs of parallel opaque lines. The opaque lines have essentially the same shape and orientation, elongate along a longitudinal direction and are equidistantly arranged along a column direction that intersects the longitudinal direction. The mask further comprises first transparent sections separating in each case two opaque lines assigned to a pair of opaque lines, second transparent sections separating in each case neighboring pairs of opaque lines, and a third transparent section extending in the column direction and confining the opaque lines on a first end respectively. A phase shift of the second transparent section differs from that of the first transparent section by about 180 degree. The phase shift of the third transparent section may be equal to that of the first or the second transparent section.

The semiconductor substrate is patterned by exposing the photo mask. From each pair of opaque lines a pair of functional active areas results in the semiconductor substrate, wherein each functional active area extends along a longitudinal direction between a first and a second end. Further a parasitic active area is formed at least between each pair of functional active areas at the first end. A separation gate and a supply unit are provided, wherein the separation gate is formed above the parasitic active areas and wherein the supply unit is capable of switching off parasitic transistors comprising in each case a parasitic channel region being formed within the respective parasitic active area. The method facilitates dense sense amplifier arrangements, wherein size-dependent transistor characteristics are stabilized.

The invention also relates to a transistor pair. The transistor pair comprises a first and a second active area, wherein each active area comprises a first and a second source/drain region and a channel region separating the source/drain regions. The source/drain regions and the channel region are arranged along a longitudinal direction between a first and a second end respectively. Each active area is assigned to one of the transistors of the transistor pair, and the active areas are arranged parallel to each other. The transistor pair comprises further a parasitic active area extending in a column direction that intersects the longitudinal direction, adjoins the functional active areas at the first end, and comprises at least a section of a parasitic channel region that adjoins the second source/drain regions. A separation gate is arranged above the parasitic channel region and is capable of suppressing a formation of a conductive channel within the parasitic channel region.

The invention also relates to a sense amplifier arrangement that comprises a plurality of isolation transistors being arranged in pairs, wherein each transistor pair comprises a first and a second active area, each active area comprising two source/drain regions and a channel region separating the source/drain regions, the source/drain regions and the channel region being in each case arranged along a longitudinal direction. The isolation transistors are arranged along a column direction, which is perpendicular to the longitudinal direction. Parasitic active areas extend in each case along the column direction, adjoin at least a pair of active areas at the first ends and comprise at least sections of parasitic channel regions that are in each case adjacent to the second source/drain regions of the isolation transistors. A separation gate is arranged above the parasitic channel regions and is capable of suppressing the formation of conductive channels within the parasitic channel regions. The arrangement saves space and ensures at the same time stable sense driver properties.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The disclosure will present in detail the following description of exemplary embodiments with reference to the following Figures.

FIGS. 1A-1C illustrate a method of manufacturing a transistor pair using an alternating phase shift mask according to a first embodiment of the invention via plan views of sections of a photo mask and a semiconductor substrate.

FIGS. 2A-2B are plan views of a cell array and a multiplexer section of a sense amplifier arrangement.

FIGS. 3A-3B are diagrams illustrating process windows for a multiplexer arrangement using a conventional photo mask and an alternating phase shift mask.

FIG. 4 is a simplified plan view of a section of a first photo mask for the formation of active areas, wherein the illustrated section corresponds to a multiplexer section of a sense amplifier arrangement according to an embodiment of the invention and wherein the photo mask comprises transparent sections of different phase.

FIG. 5 is a simplified plan view of a section of a second photo mask for the formation of active areas, wherein the illustrated section corresponds to a multiplexer section of a sense amplifier arrangement according to a further embodiment of the invention and wherein the photo mask comprises transparent sections of different phase and a connection line separating transparent sections of different phase.

FIG. 6 is a simplified plan view of a section of a third photo mask for the formation of active areas, wherein the illustrated section corresponds to a multiplexer section of a sense amplifier arrangement according to a further embodiment of the invention and wherein the photo mask comprises transparent sections of different phase, sub resolution phase assist structures and a segmented connection line separating exclusively transparent sections of different phase.

FIG. 7 is a simplified plan view of a section of a fourth photo mask for the formation of active areas, wherein the illustrated section corresponds to a multiplexer section of a sense amplifier arrangement according to a further embodiment of the invention and wherein the photo mask comprises an inverted arrangement of transparent sections of different phase and a connection line separating transparent sections of different phase.

FIGS. 8A-8C illustrate a method of manufacturing a multiplexer section of a sense amplifier arrangement using an alternating phase shift mask according to another embodiment of the invention via plan views of a section of semiconductor substrate.

### DETAILED DESCRIPTION

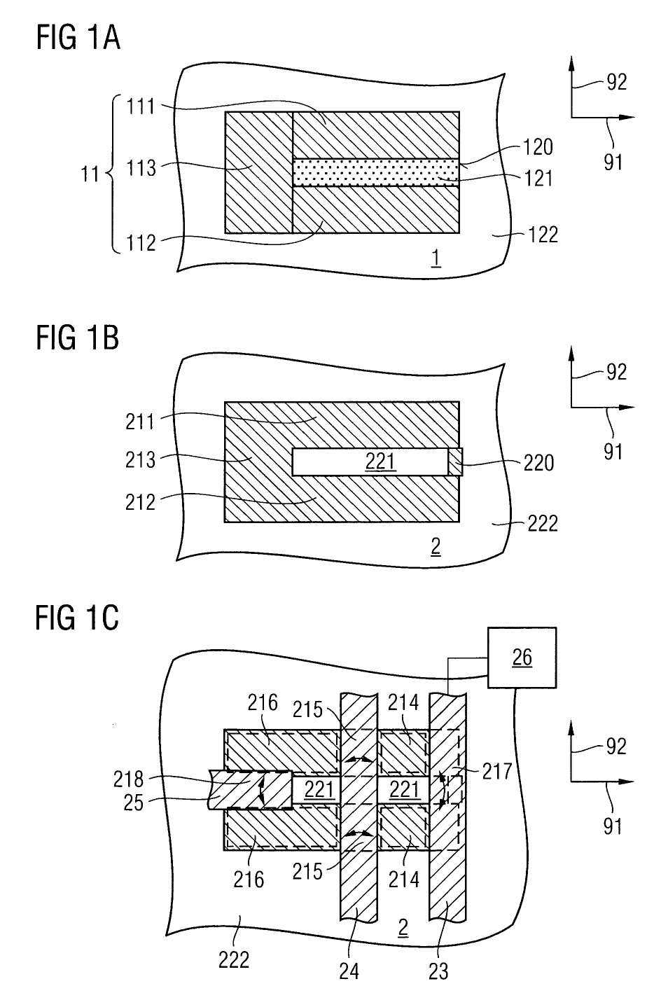

FIGS. 1A-1C refer to a method of manufacturing a transistor arrangement comprising a transistor pair according to a first embodiment of the invention. FIG. 1A shows a plan view of a section of a photo mask 1 that comprises opaque features 11, first transparent sections 121 and second transparent sections 122. The opaque features include a first and a second opaque line 111, 112 of rectangular shape respectively. The first and the second opaque lines 111, 112 extend in each case along a longitudinal direction 91 between a first and a second end and are arranged along a column direction 92 that is perpendicular to the longitudinal direction 91. A further opaque area 113 adjoins both opaque lines 111, 112 at the respective second end. At the first ends of the opaque lines 111, 112 the topology formed by the opaque features 11 is open.

The photo mask 1 comprises further a first transparent section 121 separating the opaque lines 111, 112 and a second transparent section 122 facing the first transparent section 121 at the opaque lines 121, 122 and confining to the first transparent section 121 in sections. In this example, the second transparent section 122 surrounds the opaque features 11 and confines to the first transparent section 121 along an edge 120 extending between opposing edges of the first ends of the opaque lines 111, 112.

Referring to FIG. 1B, the mask pattern comprising the opaque features 11 is projected into a resist layer covering a substrate 2 by exposing photo mask 1, wherein the etching resistance of exposed sections of the resist layer is altered with respect to the etching resistance of non-exposed sections. For example, by etching exposed sections selectively to unexposed sections an etch mask is provided. Via the etch mask a surface section of the substrate 2, for example a silicon wafer, is patterned.

FIG. 1B illustrates a plan view of a section of substrate 2. The pattern in the surface section of substrate 2 comprises two functional active areas 211, 212 corresponding to the opaque lines 111, 112 and a block area 213 that corresponds to the opaque area 113. The active areas 211, 212 have approximately a rectangular shape, wherein the degree of approximation to the rectangular shape is determined by the process parameters. The first and the second active areas 211, 212 extend in each case along a longitudinal direction 91 between a first and a second end and are arranged in a column direction 92 that is perpendicular to the longitudinal direction 91. A first insulating region 221 separates the functional active areas 211, 212. A second insulating region 222 surrounds the active areas 211, 212, 213 in the rest. The first and the second insulating regions 221, 222 are assigned to the first and second transparent sections 121, 122.

Due to the phase conflict along the edge 120, a parasitic area 220 is formed at the first ends and connects the functional active areas 211, 212. The parasitic area 220 would short circuit impurity regions formed within the functional active areas 211, 212 at the first end, for example if the parasitic area 220 is also doped during the formation of the impurity regions.

As illustrated in FIG. 1C, which shows a further plan view of substrate 2 according to FIG. 1B, a separation gate 23 is provided. Separation gate 23 is arranged above the parasitic area 220. According to this exemplary embodiment, an isolation gate 24 crossing the functional active areas 211, 212 and a connection gate 25 covering a section of block area 213 may also be provided. In alternative embodiments, each active area 211, 212 may be assigned to another gate structure and/or the block area 213 may be omitted, wherein in the latter case an additional parasitic area may be formed between the second ends of the active areas 211, 212. Then a dopant may be implanted with the separation gate 23, the isolation gate 24 and the connection gate 25 as implantation mask shielding underlying portions of the active areas 211, 212, the parasitic area 220 and the block area 213 against the dopant. The resulting impurity regions form first and second source/drain regions 214, 216 of a transistor pair. The first and second source/drain regions 214, 216 of each active area 211, 212 are separated in each case by a functional channel region 215 below the isolation gate 24. A channel region 218 below the connection gate 25 separates the second source/drain regions 216 and a parasitic channel region 217 that is formed partly within the parasitic area 220 separates the first source/drain regions 214. As separation gate 23 shields the parasitic area 220 during the implantation, a short circuit between the first source/drain regions may be avoided.

A gate dielectric (not shown) may separate separation gate 23 and parasitic area 220. The separation gate 23 may be connected to a supply unit 26 that is capable to control separation gate 23 such that a formation of a conductive channel within the parasitic channel region 217 and between the first source/drain regions 214 is suppressed, wherein a parasitic transistor formed by the first source/drain regions 214 and the parasitic channel region 217 is switched off by the supply unit 26.

Alternating phase shift masks facilitate a better lithographic performance in view of a flexible ratio of line width to line distance and in view of line width stability. With regard to a pair of parallel transistors having the same shape, the channel width may exceed the distance between the transistors significantly. Thus, the formation of wide channel transistors in a comparable small distance to each other becomes possible, wherein at the same time the channel width is comparable independent from process fluctuations (imperfections). Parasitic areas in the semiconductor substrate 2 that result from a phase conflict on an open end of the transistor pair are not removed but accepted and may be deactivated by the separation gate such that they remain without effect on the functionality of the transistor pair. In typical applications, the separation gate 23 does not require additional space, such that the inventive application of the alternating phase shift mask does not negatively impact the chip size.

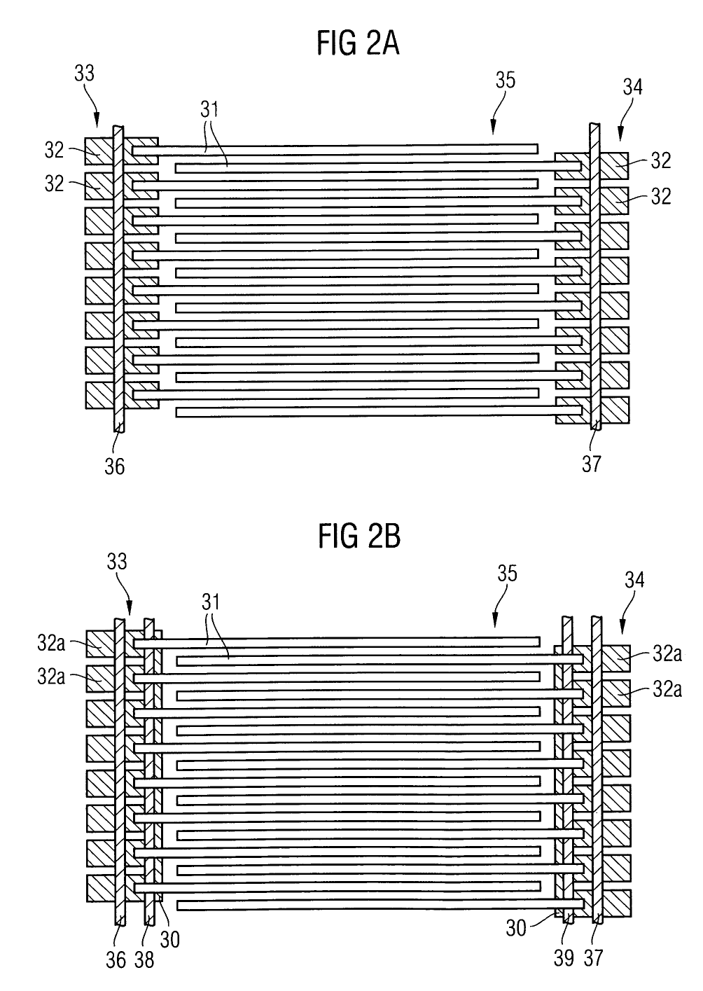

FIG. 2A refers to a layout of a multiplexer section of a sense amplifier circuit of a memory cell array. In a memory cell array 35 realizing a folded bit line architecture, each bit line 31 requires an access to a corresponding sense amplifier stage, wherein in each case an isolation transistor 32 is arranged between the bit line 31 and the rest of the sense amplifier stage. The isolation transistors 32 are typically arranged in two columns 33, 34 adjoining the memory cell array 35 on opposing sides as illustrated in FIG. 2A, wherein the bit lines 31 of the memory cell array 35 are connected alternately to isolation transistor 32 in the first column 33 and to isolation transistors 32 of the second column 34. The isolation transistors 32 of each column 33, 34 are controlled commonly by one common isolation gate line 36, 37. The number of isolation transistors 32 in each column 32, 34 is half the number of bit lines 31 and the isolation transistors 32 may therefore be provided with the double bit line pitch. The arrangement in two columns 33, 34 facilitates a dense and space saving arrangement compared to conventional layouts providing the isolation transistors 32 displaced against each other, wherein the isolation transistors 32 may be arranged in two zigzag lines.

Since the sensed signal on the bit lines should be deteriorated as little as possible, the channel width of the isolation transistors 32 should be as large as possible. As a result, the width of active areas of the isolation transistors may exceed the distance of neighboring active areas of the isolation transistors 32 in order to achieve a better performance of the memory cell array 35. Since the isolation transistors 32 are arranged in the critical sense path, the physical dimensions of the isolation transistors 32 of the memory cell array, a memory device, a wafer or a wafer lot should be stable and should remain unaffected by process fluctuations (imperfections).

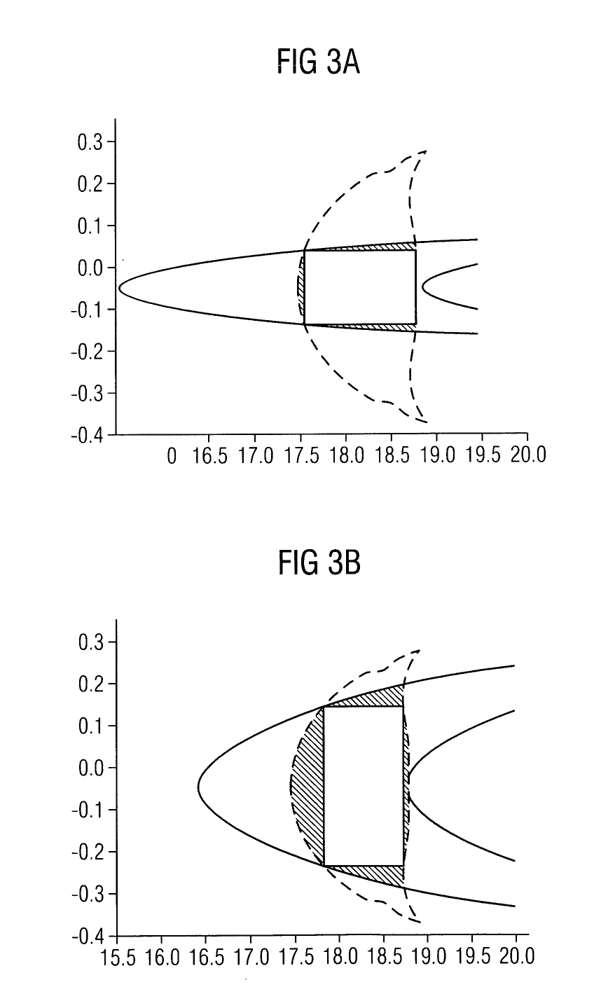

FIGS. 3A and 3B are diagrams with the defocus in micrometer plotted against the exposure dose in mJ/cm². The dotted line 3a refers in each case to the resulting process window for the cell array. The continuous lines refer in each case to the process windows for a multiplexer topology as illustrated in FIG. 2A.

FIG. 3A illustrates the overlapping process window for isolation transistors arranged in a column of equidistant transistor pairs as described in FIG. 1C, wherein a conventional chrome mask is provided for the exposure. At the nominal line width, a depth of focus of about 200 nm may be achieved. The total process window is 1.16 percent micrometer.

FIG. 3B illustrates the overlapping process window for the same arrangement, wherein an alternating phase shift mask is used that comprises an additional opaque line connecting the first ends of the isolation transistors. First and second transparent sections separate the opaque lines assigned to the isolation transistors in alternating order, such that in each case a first and a second transparent section face each other at the long sides of the opaque lines. The phase shift of the first transparent section differs from that of the second transparent section by 180 degree. The depth of focus at the nominal line width is 370 nanometers and surpasses that of the conventional mask by 80 percent. The total process window is 1.77 percent micrometer and exceeds the corresponding value of the conventional mask by about 50 percent. The use of an alternating phase shift mask in this application facilitates the formation of wider transistors with more stable channel widths and transistor performance.

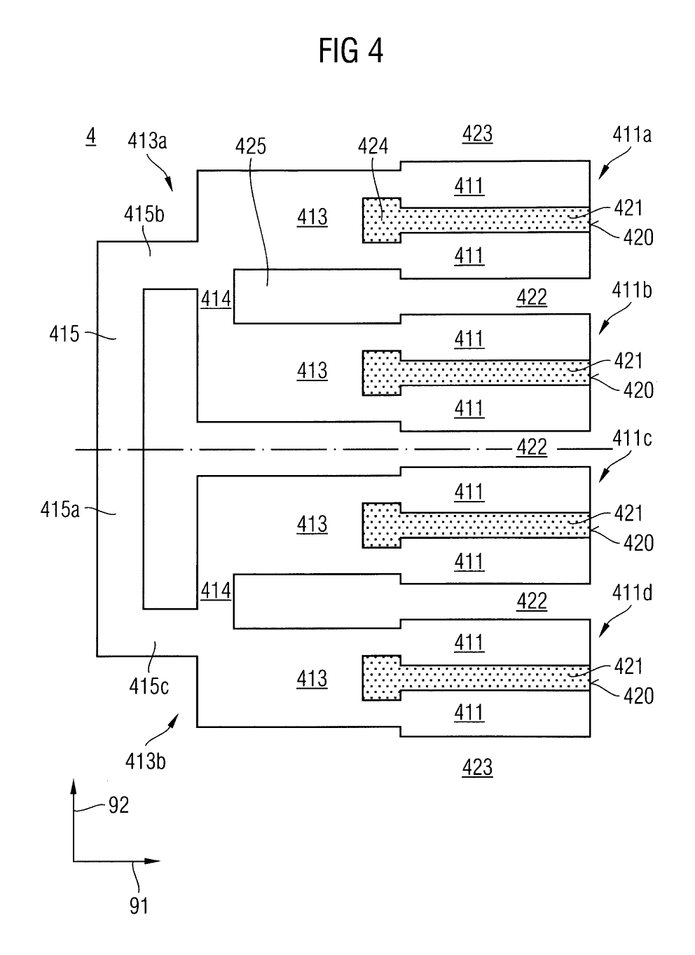

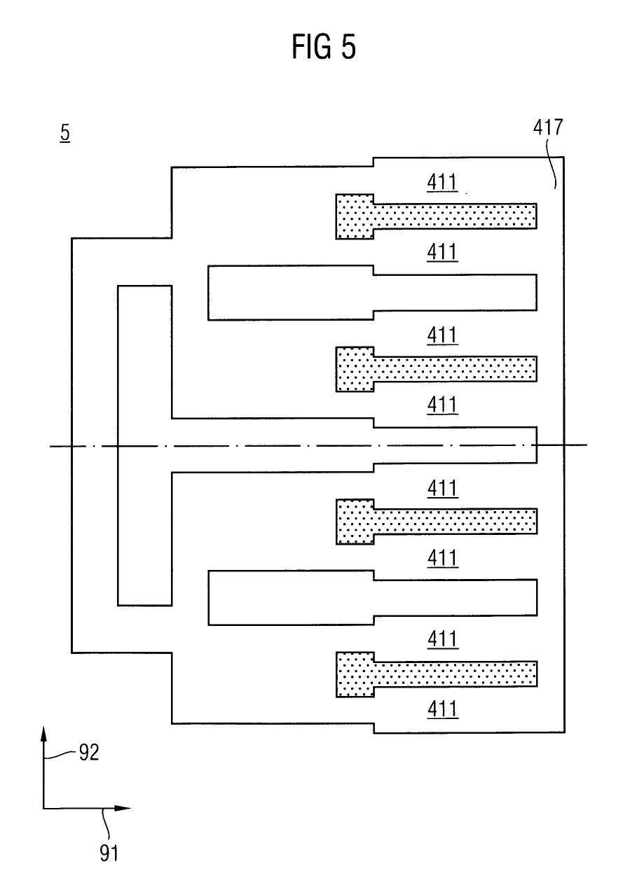

FIG. 4 is a plan view of a section of a photo mask 4. By exposing the illustrated section, a surface section of a semiconductor substrate is patterned, wherein active areas of a transistor multiplexer are formed that realizes an isolation/equalizing/precharge functionality of a sense amplifier arrangement for a memory cell array. The photo mask 4 comprises four pairs 411a-d of opaque lines 411 that correspond to four isolation transistor pairs in the patterned substrate. Each opaque line 411 has a rectangular shape and extends along a longitudinal direction 91 between a first end on the right hand side and a second end on the left hand side. The opaque lines 411 are equidistantly arranged along a column direction 92, which is perpendicular to the longitudinal direction 91. The opaque lines 411 are “open” at the first end, i.e., no functional opaque feature adjoins the opaque lines 411 at the open end.

On the second ends of the opaque lines 411, each pair of opaque lines 411a-d is connected to an opaque area 413. Each opaque area 413 corresponds to an equalizer transistor in the patterned semiconductor substrate, wherein each equalizer transistor connects neighboring isolation transistors on the sense amplifier side when being addressed. The opaque areas 413 have rectangular shape and are equidistantly arranged along the column direction 92.

The opaque areas 413 are arranged in pairs 413a, 413b. The opaque areas 413 of each pair 413a, 413b are connected by a first precharge line 414. Each first precharge line 414 extends along the column direction 92 and adjoins the respective opaque area 413 at that end that faces the opaque lines 411 at the respective opaque area 413. A second precharge line 415 connects the two pairs 413a, 413b of opaque areas 413. The second precharge line 415 comprises a first section 415a extending along the column direction 92 near to the first precharge lines 414. A second section 415b elongates along the longitudinal direction 91 and connects a first end of the first section 415a to a first pair 413a of opaque areas 413 at that end that faces the opaque lines 411. A third section 415c elongates along the longitudinal direction 91 and connects a second end of the first section 415a to a second pair 413b of opaque areas 413 at that end that faces the opaque lines 411.

First transparent sections 421 separate in each case the opaque lines 411 of each pair 411a-d of opaque lines. Second transparent sections 422 separate in each case pairs 411a, 411b, 411c, 411d of opaque lines 411. A third transparent section 423 surrounds the opaque features and confines to the first transparent sections 421 in each case along an edge 420 extending along the column direction 92 at the open end of the pairs 411a, 411b, 411c, 411d of opaque lines 411. One of the second transparent sections 421 separates the second precharge line 415 from the opaque areas 413 and the first precharge lines 414. The phase shift of the first transparent section 421 differs from that of the second and third transparent sections 422, 423 by 180 degree. By way of example, the second transparent sections 422 and the third transparent section 423 do not shift the phase, whereas the first transparent sections 421 shift the phase by 180 degree.

Along the column direction 92 transparent sections 421, 422 of different phase shift alternate such that each opaque line 411 is confined by transparent sections of different phase along the longitudinal direction 91, such that during exposure destructive interference supports the formation of line-shaped active areas corresponding to the opaque features 411, 413, 414, 415. Resolution enhancement features 424, 425 support the formation of the end portions of the adjacent lines. The phase conflict along the edges 420 results in the formation of parasitic active areas in the patterned semiconductor substrate between the active areas corresponding to the opaque lines 411 that are assigned to the respective edge 420.

FIG. 5 is a plan view of a section of a further photo mask 5 according to an exemplary embodiment of the invention. The photo mask 5 differs from that as illustrated in FIG. 4 in an additional, non-functional opaque assist line 417 extending in the column direction 92 and connecting the opaque lines 411 at the respective first end. The opaque assist line 417 allows the adjustment of the width of the resulting parasitic areas connecting the active areas in the semiconductor substrate.

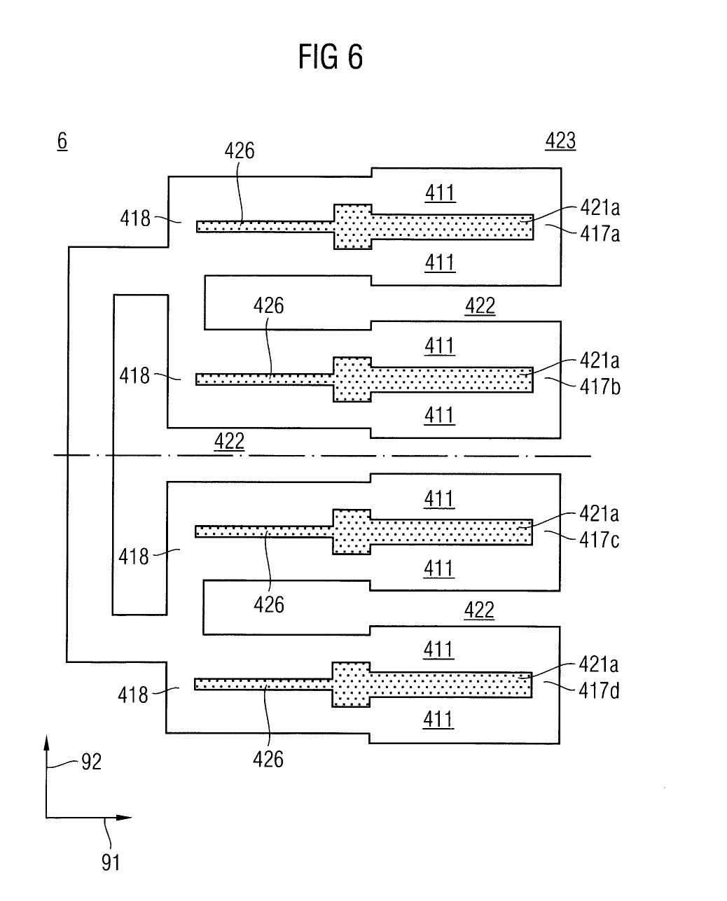

A section of a further photo mask 6 is shown in FIG. 6. Modified first transparent sections 421a of photo mask 6 differ from the first transparent sections 421 of photo mask 4 in comprising sub resolution phase assist structures 426 splitting up symmetrically the respective opaque area 418 along the longitudinal direction 91, wherein the width of the opaque areas 418 may be stabilized. Segments 417a-d of a segmented opaque assist line separate the modified first transparent sections 421a from the third transparent section 423, wherein the second transparent sections 422 confine directly to the third transparent section 423. The segments 417a-d of the segmented opaque assist line are exclusively provided along that edges along which a phase conflict may occur.

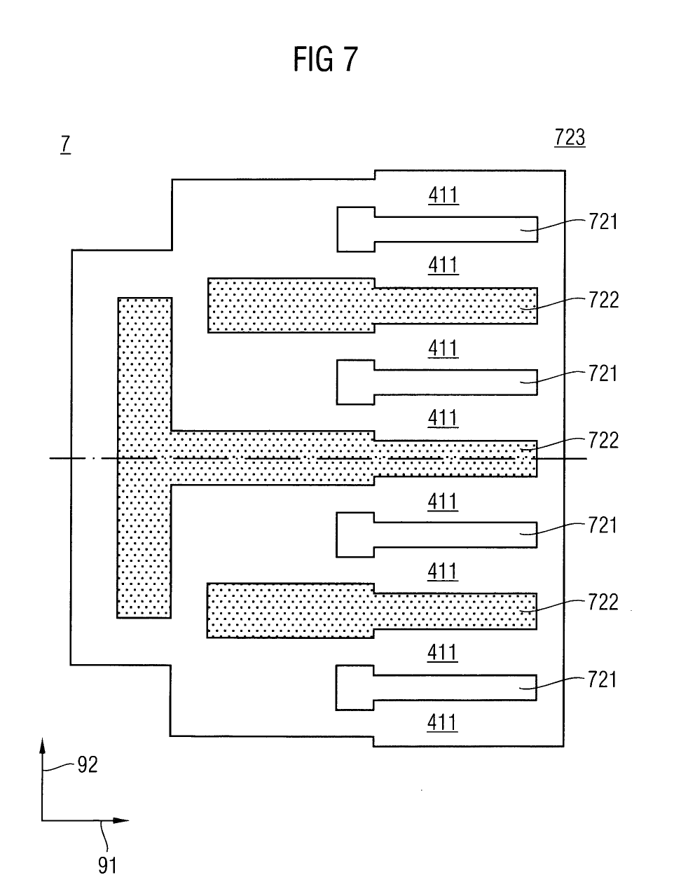

FIG. 7 is a plan view of a further photo mask 7, wherein the phase shift of the first and second transparent sections 721, 722 is inverted with reference to the phase shift of the third transparent section 723. By way of example, the first transparent sections 721 and the third transparent section 723 do not shift the phase, whereas the second transparent sections 722 shift the phase by 180 degree. The second precharge line 415 is confined by opposing second and third transparent sections 722, 723, such that a corresponding precharge area in the semiconductor substrate may be stabilized by providing photo mask 7 as alternating phase shift mask. A section of the third transparent section 723 confining to the respective outer opaque lines 411 on the side opposing the first transparent section 721 may be provided with the phase shift characteristic of the second transparent section 722 by using conventional techniques.

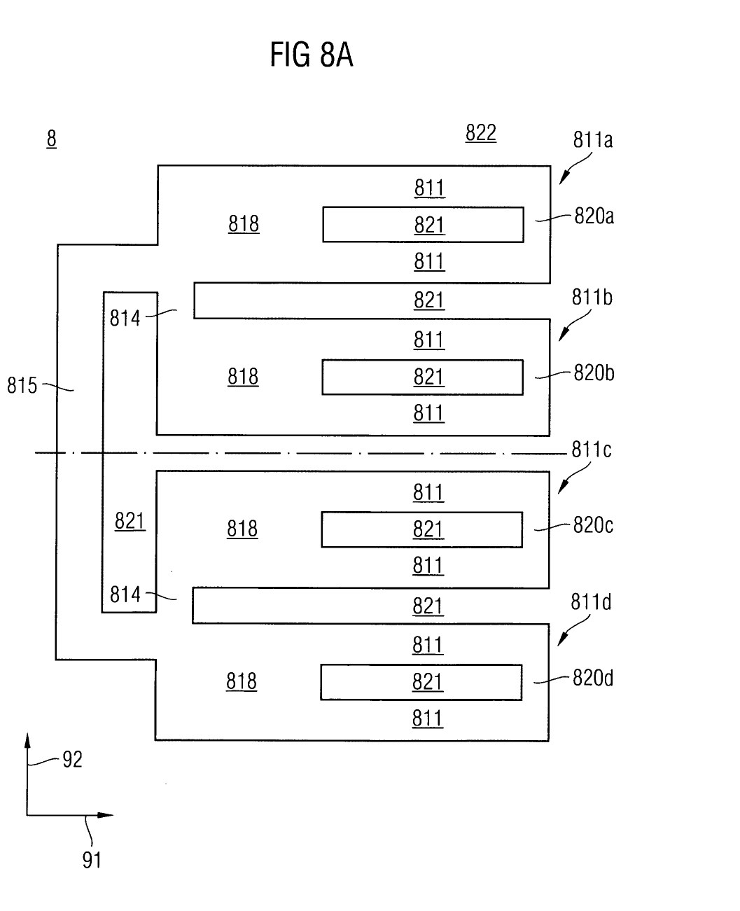

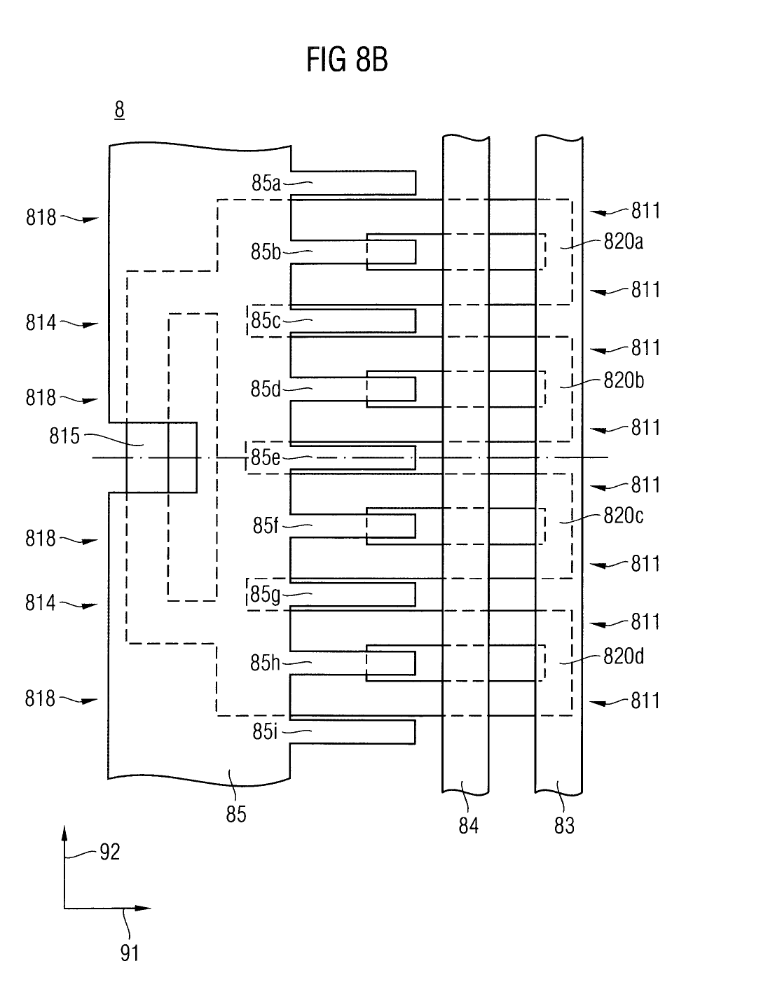

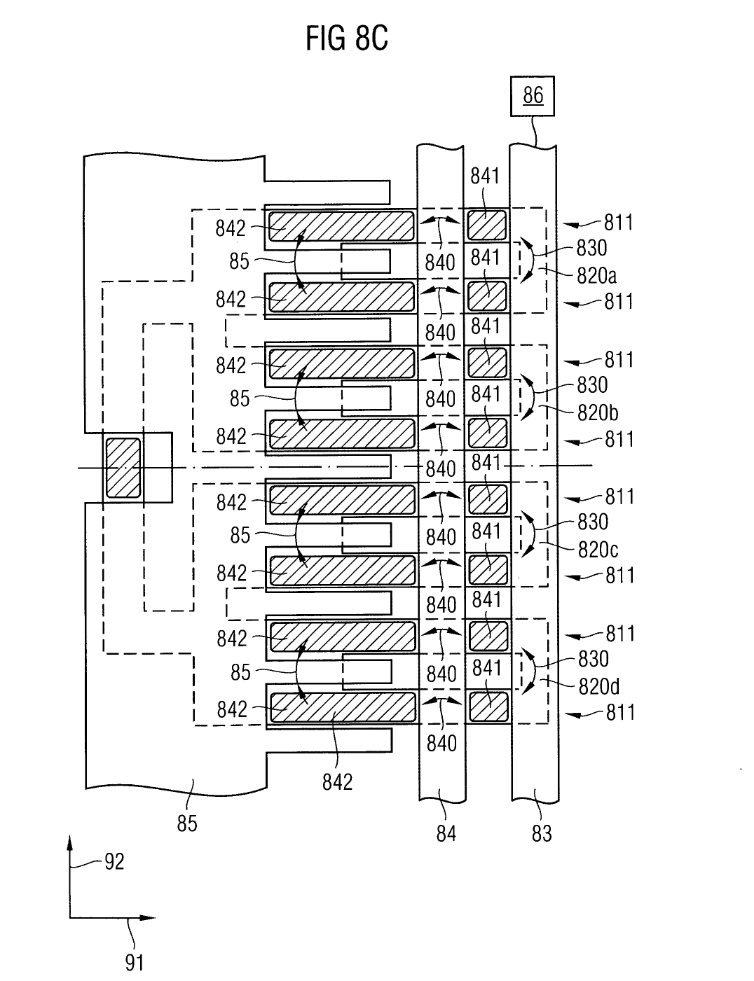

FIG. 8 shows plan views of a section of a sense amplifier arrangement resulting from the use of a photo mask 6 as illustrated in FIG. 6 and refers to an exemplary method of manufacturing a multiplexer transistor of a sense amplifier arrangement, wherein the multiplexer transistor covers an isolation/equalizing/precharge functionality. A surface section of a semiconductor substrate, for example a silicon wafer, which may be p-doped at least in parts, is patterned by depositing successively a hard mask and a photo resist layer on a pattern surface of the semiconductor substrate, projecting the mask pattern into the photo resist layer, developing the photo resist, and transferring the pattern of the photo resist in the hard mask and from the hard mask into the semiconductor substrate by suitable etch processes.

FIG. 8A is a plan view of a section of a semiconductor substrate 8 after transferring the mask pattern into the semiconductor substrate 8. Each opaque feature of photo mask 6 corresponds to a fin or mesa in the surface section of semiconductor substrate 8. Each transparent section 421a, 422, 423 of photo mask 6 corresponds to a groove in the substrate material, wherein the grooves may be filled with an insulator material. The pattern in the surface section of semiconductor substrate 8 comprises four pairs 811a-d of functional active areas 811, each active area 811 corresponding to one of the opaque lines 411, and four block areas 818 that correspond in each case to one of the opaque areas 418. Each active area 811 has approximately a rectangular shape, wherein the degree of approximation to the rectangular shape is determined by the exposure and etch process parameters. The active areas 811 extend in each case along a longitudinal direction 91 between a first and a second end and are arranged in a column direction 92 that is perpendicular to the longitudinal direction 91. The functional active areas 811 are separated in each case by a first insulating region 821. A second insulating region 822 surrounds the active areas 811, the precharge areas 814, 815 and the block areas 818 in the rest. The first insulating regions 821 result from the first and second transparent sections 421a, 422. The second insulating region 822 results from the third transparent section 423.

Due to the phase conflict along the edges 420 and/or corresponding to the segments 417a-d of the segmented opaque assist line, parasitic areas 820a-d are formed at the first ends and connect in each case a pair of the neighboring functional active areas 811. Each parasitic area 820a-d would short circuit impurity regions formed within the functional active areas 811 assigned to the same block area 818 at the first end, especially if the parasitic area 820a-820d were also doped during the formation of the impurity regions.

With reference to FIG. 8B, gate structures 83, 84, 85 are provided that cross the active areas along the column direction 92. The gate structures 83, 84, 85 may comprise a polysilicon layer and a gate dielectric separating the polysilicon layer and the active areas. As illustrated in FIG. 8B, which shows a further plan view of the semiconductor substrate 8 according to FIG. 8A after the formation of the gate structures 83-85, a separation gate 83 is provided that covers the segmented parasitic areas 820a-820d. An isolation gate 84 crosses the functional active areas 811 and an equalizer gate 85 covers a section of the block areas 818, the first precharge lines 814 and sections of the second precharge line 815. Fingers 85a-85i of the equalizer gate 85 extend in the longitudinal direction 91, wherein each even finger is arranged symmetrically in the middle of a corresponding block area 818 and leaves two portions of the respective block area 818 facing each other at the respective finger uncovered. The odd fingers support the formation of the even fingers. The equalizer gate 85 leaves a middle portion of the second precharge line 815 uncovered so as to facilitate the formation of a contact to a connectivity line.

Referring to FIG. 8C, dopants may be implanted with the separation gate 83, the isolation gate 84 and the equalizer gate 85 as implantation mask shielding underlying portions of the active areas 811, the parasitic areas 820a-d, the block areas 818 and the precharge areas 814, 815 against the dopants. The resulting impurity regions, which may be n-doped, form first and second source/drain regions 841, 842 of isolation transistors. The first and second source/drain regions 841, 842 of each active area 811 are separated in each case by a channel region 840 below the isolation gate 84. A channel region 850 below the equalizer gate 85 separates the second source/drain regions 842 assigned to a block area 818 respectively. Parasitic channel regions 830 that are in each case formed partly within the respective parasitic area 820a-d separate in each case neighboring first source/drain regions 841. As separation gate 83 shields the parasitic areas 820a-d during the implantation, a short circuit between the first source/drain regions 841 may be avoided.

The separation gate 83 may be connected to a supply unit 86 that is capable to control separation gate 83 such that a formation of a conductive channel within the parasitic channel region 830 and between neighboring first source/drain regions 841 is suppressed, wherein parasitic transistors that may be formed by the first source/drain regions 814 and the parasitic areas 820a-d are switched off by the supply unit 86. Depending on the position of an outer edge of the separation gate 83 with reference to an outer edge of the segmented parasitic areas 820a-d, the separation gate 83 may leave an outer section facing the isolation transistor at the separation gate 83 uncovered, such that further impurity regions (not shown) facing the first source/drain regions 841 at the separation gate 83 may be formed during the implantation step. In this case, a pair of parasitic transistors may be formed between the first source/drain regions 841 within the parasitic area 820, wherein the separation gate 83 may switch off both transistors.

By using the alternating phase shift masks a better lithographic performance is achieved in view of a flexible ratio of line width to line distance and in view of line width stability. With regard to a pair of parallel transistors having the same shape, the channel width may exceed the distance between the transistors significantly. Thus, the formation of wide channel transistors in a comparable small distance to each other becomes possible, wherein at the same time the channel width becomes more independent from process fluctuations (imperfections). Parasitic areas in the semiconductor that result from a phase conflict on an open end of the transistor pair are not removed but accepted and may be deactivated by the separation gate such that they remain without effect on the functionality of the neighboring transistors. In typical applications, the separation gate does not require additional space, such that the inventive application of the alternating phase shift mask does not negatively impact the chip size. In a further exemplary embodiment, the separation transistors may be formed in the manner of the equalizer transistors and expand or substitute the equalizer transistors as described above.

While the invention has been described in detail with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SIGNS

1 photo mask
11 opaque features
111 first opaque line
112 second opaque line
113 opaque area
120 edge
121 first transparent section
122 second transparent section
2 substrate
211 first active area
212 second active area
213 block area
214 first source/drain region
215 functional channel region
216 second source/drain region
217 parasitic channel
218 block channel region
220 parasitic area
221 first insulating region
222 second insulating region
23 separation gate
24 isolation gate
25 connection gate
30 parasitic areas
31 bit line
32 isolation transistor
32a isolation transistor
33 column
34 column
35 memory cell array
36 gate line
37 gate line
38 separation gate
39 separation gate
4 photo mask
411 opaque line
411a-d pair of 411
413 opaque area
413a,b pair of 413
414 first precharge line 415 second precharge line
415a first section of 415
415b second section of 415
415c third section of 415
417 opaque assist line
417a-d segments of segmented opaque assist line
418 opaque area
420 edge
421 first transparent section
421a first transparent section
422 second transparent section
423 third transparent section
424 resolution enhancement feature
425 resolution enhancement feature
426 sub resolution phase assist structure
5 photo mask
6 photo mask
7 photo mask
721 first transparent section
722 second transparent section
723 third transparent section
8 semiconductor substrate
811 active area
811a-d pairs of 811
814 first precharge area
815 second precharge area
818 block area
818a,b pairs of 818
820a-d parasitic areas
821 second insulating region
822 first insulating region
83 separation gate
830 channel region
84 isolation gate
840 channel region
841 first source/drain region
842 second source/drain region
85 equalizer gate
85a-i fingers of 85
850 channel region
91 longitudinal direction
92 column direction

What is claimed is:

1. A method of forming a transistor pair via an alternating phase shift mask, the method comprising:
providing a photo mask comprising opaque features including a pair of opaque lines being separated by a gap, with a first transparent section filling the gap between the opaque lines and a second transparent section extending outside the gap from one of the opaque lines to the other and facing the first transparent section at the opaque lines at least in sections, wherein a phase shift of the second transparent section differs from a phase shift of the first transparent section;
patterning a semiconductor substrate by exposing the photo mask so as to form functional active areas of a transistor pair in the semiconductor substrate from the opaque lines, wherein each of the functional active areas extends in a longitudinal direction between a first end and a second end, and the functional active areas are arranged in a column direction that intersects the longitudinal direction with at least one parasitic active area being formed that connects the functional active areas at their respective first ends;
providing a separation gate above the parasitic active area; and
providing a supply unit that switches off a parasitic transistor comprising a parasitic channel region formed within the parasitic active area.

2. The method of claim 1, wherein the parasitic active area extends along a line corresponding to an edge of the first transparent section.

3. The method of claim 1, wherein the parasitic active area extends along the column direction.

4. The method of claim 1, wherein the supply unit is capable of permanently switching off the parasitic transistor in an operation mode of the transistor pair.

5. The method of claim 1, wherein the column direction is perpendicular to the longitudinal direction.

6. The method of claim 1, wherein the phase shift of the first and second transparent sections differ by 180 degrees.

7. The method of claim 1, wherein the opaque lines are parallel.

8. The method of claim 1, wherein the opaque lines are the same length.

9. The method of claim 1, further comprising:
forming at least two source/drain regions and a channel region, wherein the channel region separates the respective source/drain regions within the functional active areas, and the at least two source/drain regions include a first source/drain region that adjoins the parasitic active area.

10. The method of claim 9, wherein the opaque features further comprise an opaque area adjoining both opaque lines at their respective second ends and partially confining the first transparent section, and the method further comprises:
forming a block area within the semiconductor substrate by exposing the photo mask, wherein the block area adjoins both functional active areas at the second ends.

11. The method of claim 1, wherein the functional active areas have widths that exceed a distance between the functional active areas by at least 20%.

12. The method of claim 1, wherein the opaque features further comprise an opaque assist line extending between the opaque lines so as to separate the first transparent section from the second transparent section.

13. A method of forming an equalizing/precharge portion of a sense amplifier arrangement, the method comprising:
providing a photo mask including opaque features comprising a plurality of pairs of opaque lines that have substantially the same shape and orientation, extend in a longitudinal direction and are uniformly arranged along a column direction intersecting the longitudinal direction, the mask further comprising first, second and third transparent sections, each first transparent section separating two opaque lines of a pair of opaque lines, each second transparent section separating adjacent pairs of opaque lines, and each third transparent section extending in the column direction and confining the opaque lines on respective first ends of the opaque lines, wherein the second transparent sections comprise a phase shift that differs from a phase shift of the first transparent sections by 180 degrees;
patterning a semiconductor substrate by exposing the photo mask such that a pair of functional active areas form from each pair of opaque lines, each functional active area extending in the longitudinal direction between a first end and a second end so as to form a parasitic active area between each pair of functional active areas at the respective first ends;
providing a separation gate above the parasitic active areas; and
providing a supply unit that switches off parasitic transistors, each transistor comprising a parasitic channel region formed within the parasitic active area.

14. The method of claim 13, wherein the functional active areas have widths that exceed a distance between the functional active areas by at least 20%.

15. The method of claim 13, further comprising:
providing an isolation gate crossing the functional active areas; and
forming impurity regions in each functional active area on both sides of the isolation gate, such that in each functional active area an isolation transistor of the sense amplifier arrangement is formed.

16. The method of claim 15, wherein the opaque features further comprise a plurality of opaque areas, each opaque area adjoining both opaque lines of one of the pairs of opaque lines and the corresponding first transparent section, and the method further comprises:
forming a plurality of block areas within the semiconductor substrate by exposing the photo mask, each block area adjoining a pair of functional active areas at the respective second ends.

17. The method of claim 16, further comprising:
providing an equalizer gate crossing the block areas so as to form equalizer transistors of the sense amplifier arrangement, each of the equalizer transistors comprising a channel region below the equalizer gate and impurity regions arranged at the second ends of the respective active areas of the assigned pair of functional active areas.

18. The method of claim 13, wherein the opaque features further comprise opaque assist lines connecting the opaque lines at the first end.

19. A transistor pair, comprising:
a first and a second active area, each active area comprising a first source/drain region, a second source/drain region and a channel region separating the first and second source/drain regions, the source/drain regions and the channel region being arranged in a longitudinal direction between a first end and a second end respectively, each active area being assigned to one of the transistors of the transistor pair, and the active areas being arranged parallel to each other;
a parasitic active area extending in a column direction intersecting the longitudinal direction, the parasitic active area adjoining the first and second active areas at their respective first ends, and comprising at least a section of a parasitic channel region adjoining the second source/drain regions; and
a separation gate arranged above the parasitic channel region and configured to suppress a formation of a conductive channel within the parasitic channel region.

20. The transistor pair of claim 19, wherein the column direction extends perpendicular to the longitudinal direction.

21. The transistor pair of claim 19, wherein the active areas of the transistors have predetermined widths that exceed a predetermined distance between the active areas of the transistors by at least 20%.

22. The transistor pair of claim 19, further comprising:
a supply unit connected to the separation gate and configured to supply an inhibit bias suitable for suppressing the formation of a conductive channel within the parasitic channel region.

23. The transistor pair of claim 22, wherein the supply unit supplies the inhibit bias permanently.

24. A transistor arrangement, comprising:
a plurality of transistor pairs, each transistor pair comprising a first functional active area and a second functional active area, each functional active area comprising a first source/drain region, a second source/drain region and a channel region separating the first and the second source/drain regions, the source/drain regions and the channel region being arranged along a longitudinal direction between a first end and a second end of the functional active area, wherein the functional active areas extend in the longitudinal direction and are arranged parallel to each other, and the plurality of transistor pairs are arranged in a column direction that is perpendicular to the longitudinal direction;
parasitic active areas extending in the column direction, wherein each parasitic active area adjoins the functional active areas of one of the transistor pairs at a first end and comprises a parasitic channel region adjoining the second source/drain regions of the respective transistor pair; and
a separation gate arranged above the parasitic channel regions configured to suppress a formation of conductive channels within the parasitic channel regions.

25. A sense amplifier arrangement, comprising:
a plurality of isolation transistors arranged in pairs, each transistor pair comprising a first active area and a second active area, each active area comprising two source/drain regions and a channel region separating the source/drain regions, and each of the source/drain regions and the channel region being arranged in a longitudinal direction, wherein the isolation transistors are arranged in a column direction that is perpendicular to the longitudinal direction;
parasitic active areas extending along the column direction, each parasitic active area adjoining at least a pair of active areas at the first end and comprising at least sections of parasitic channel regions being adjacent to the second source/drain regions of the isolation transistors; and
a separation gate arranged above the parasitic channel regions and configured to suppress a formation of conductive channels within the parasitic channel regions.

26. The sense amplifier arrangement of claim 25, further comprising:
a plurality of equalizer areas formed within the semiconductor substrate, each equalizer area adjoining the active areas of each isolation transistor pair at the second end, wherein each of the first source/drain regions is connected to an equalizer channel region that is formed within the assigned equalizer area; and
an equalizer gate arranged above the equalizer channel region and configured to control conductive channels within the equalizer channel region.

27. The sense amplifier arrangement of claim 26, wherein the equalizer gate comprises:
finger sections, each finger section being assigned to one isolation transistor pair and extending in the longitudinal direction; and
two impurity regions that face each other at the respective finger section, each impurity region being connected to the second source/drain region in the adjacent active area of the isolation transistor pair.

28. The sense amplifier arrangement of claim 27, further comprising:
first precharge lines, each first precharge line connecting the equalizer areas of a pair of equalizer areas, extending in the column direction and adjoining the assigned equalizer area on a side facing the isolation transistors at the equalizer area;
wherein the equalizer gate controls a formation of conductive channels between the impurity regions formed within the adjacent equalizer areas.

29. The sense amplifier arrangement of claim 28, further comprising:
a second precharge line connecting two pairs of equalizer areas, the second precharge line comprising a first section, a second section and a third section, wherein the first section extends in the column direction, and the second and third sections extend in the longitudinal direction and connect a pair of the equalizer areas on the side of the first precharge lines with the first section; and
a precharge impurity region formed in the middle of the first section of the second precharge line;
wherein the equalizer gate controls a formation of conductive channels being formed in each case at least in sections between the impurity regions provided within the equalizer areas and the precharge impurity region.
